(19) United States
(12) Patent Application Publication
(10) Pub. No.: US 2011/0165458 A1
(43) Pub. Date: Jul. 7, 2011

(54) ELECTRICALLY CONDUCTING FIBRES FOR BIOELECTROCHEMICAL SYSTEMS, ELECTRODES MADE WITH SUCH FIBRES, AND SYSTEM INCLUDING ONE OR MORE SUCH ELECTRODES

(75) Inventors: Nicolas Mano, Talence (FR); Philippe Poulin, Talence (FR)

(73) Assignee: Centre National De La Recherche Scientifique (CNRS), Paris (FR)

(21) Appl. No.: 12/997,628

(22) PCT Filed: Jun. 8, 2009
(86) PCT No.: PCT/FR2009/051076

§ 371 Date: Feb. 24, 2011

(30) Foreign Application Priority Data
Jun. 13, 2008 (FR) 0853918

(51) Int. Cl. H01M 4/02; B32B 9/00; B05D 5/12; C25D 5/54; D01D 5/00; C25D 7/06; C25B 11/12; C25C 7/02; C25D 17/10; G01N 27/327; B82Y 99/00

(52) U.S. Cl. 429/209; 428/367; 427/113; 205/159; 264/129; 204/290.15; 204/403.15; 977/742

(57) ABSTRACT

Electrically conductive fibers made of carbon nanotubes that are assembled and covered by at least one deposit that includes a biopolymer, the manufacturing of these electrodes and the use of these electrodes in bioelectrochemical systems such as, for example, enzymatic or immunological biosensors, DNA, RNA, and biobatteries.

The invention relates to electrically conductive fibers for bioelectrochemical systems. The invention also relates to electrodes that are produced with such fibers and systems that comprise one or more such electrodes.

The invention applies to the production of bioelectrochemical systems, in particular biomedical systems, such as, for example, enzymatic and immunological biosensors, DNA, RNA and biobatteries.

### PRIOR ART

Carbon is a material of choice for the production of electrodes. Its chemical inertia actually makes it possible to explore broad ranges of potentials in electrochemistry. This is why carbon is very widely used in various forms for the production of electrochemical devices: sensors, actuators, small batteries and storage batteries. In addition, carbon has the special feature of being a material in which the organic molecules and polymers are effectively adsorbed. It is therefore possible to absorb redox polymers, enzymes or else conductive polymers there for the production of improved, better-performing, and selective electrochemical devices. It is also biocompatible and ideally lends itself to the production of devices for biological applications.

Carbon has other advantages that are mechanical strength, thermal stability, and the possibility of use in the form of “fibers” (“fiber” being defined as a system of indefinite length and a diameter of between 10 nanometers and 1 millimeter). This possibility is extremely valuable for the miniaturization of devices, the production of microelectrodes or systems that can be implanted in living organisms. The shaping of fibers is also useful because it is a means of increasing the accessible surface area for a given volume of material. In all electrochemical devices, the specific surface area is critical because it conditions the amplitude of the responses of the devices.

Taking into account these different advantages, the traditional carbon fibers have been widely studied for the production of microelectrodes, sensors, and electrochemical biobatteries. Today, they are also the most used material for the miniaturized biobatteries and the production of microelectrodes.

However, the performances of the actual materials are also limited by currents that are too weak, absorptions that are not very stable or not effective enough. For example, in the case of the biobatteries that are described in, for example, the publication by Heller, A., Anal. Bioabal. Chem. 2006, 385, 469-473 and the publication by Heller, A., Curr Opin Biotechnol 2006, 10, 664-672, the generated powers are insufficient for biomedical systems such as supplying power for implanted biosensors in particular.

The increase in the current density of a biosensor or a biobattery is a necessary stage for being able to reach respectively adequate detection limits or powers on the order of 2 μW.

To do this, it is necessary to increase the specific surface area of the electrodes.

One way of doing this is to produce materials with larger specific surface areas while preserving and even improving the properties that the carbon provides in the area of bioelectrochemical applications.

The carbon nanotubes (single-wall, double- or multi-wall) are materials that have very advantageous characteristics a priori for bioelectrochemistry. They actually consist of carbon and have a very large specific surface area because of their nanometric size. However, the nanotubes that are produced in bulk are not structured. They come in the form of a powder that cannot be used in that state for bioelectrochemical applications.

Various approaches, however, have been proposed for the modification of electrodes with carbon nanotubes.

By way of example, it is possible to cite the publication by Wang, Y.; Li, Q.; Hu, S., Bioelectrochemistry 2005, 65, 135-142. The nanotubes are deposited randomly on the surface of conductive materials or embedded in a conductive matrix. It is thus difficult to use their properties effectively, namely their specific surface area and electrical conductivity.

Other approaches consist in increasing nanotubes on conductive surfaces. It is possible to cite, for example, the article by Huang, X.-J.; Im, H.-S.; Yarimaga, O.; Kim, J.-H.; Jang, D.-Y.; Lee, D.-H.; Kim, H.-S.; Choi, Y.-K., J. Electroanal. Chem. 2006, 594, 27-34, and the article by Wang, K.; Fishman, H. A.; Dai, H.; Harris, J. S., Nano. Lett. 2006, 6, 2043-2048.

It is also possible to cite the production of simple microelectrodes based on carbon nanotube fibers produced for the detection of nicotine adenine dinucleotide (NADH). A description of this particular application is given in the article by Wang, J.; Deo, R. P.; Poulin, P.; Mangey, M., J. Am. Chem. Soc. 2003, 125, (48), 14706-14707. It involves electrodes reserved for an application that is non-bioelectrochemical and whose response is limited to the inherent response of carbon nanotubes.

Finally, another approach consisted in immobilizing nanotube fibers in a resin so as to use the cross-section of the fiber as an electroactive element. This approach is described in the article by Viry, L.; Derré, A.; Garrigues, P.; Sojic, N.; Poulin, P.; Kuhn, A., Anal. Bioanal. Chem. 2007, 389, 499-505. This type of nanotube electrode is limited for the generation of currents that are of large absolute value, taking into account the small cross-section of the fibers.

Reference can also be made to the prior art that consists of the document D1 of JOSHI, MERCHANT, WANG, SCHMIDTKE, entitled “Amperometric Biosensors Based on Redox Polymer-Carbon Nanotube-Enzyme Composites.” This document describes the production of an electrode that consists of a glassy carbon electrode (GCE) whose surface is covered with a carbon nanotube (CNT) dispersion. With the deposit technique that is used, the CNTs are oriented randomly and form a two-dimensional surface. After the CNT deposit is dried, enzymes are provided and are fixed to the CNT, whereby a redox polymer is used for this purpose.

In a second experiment that is described, enzymes are mixed in the CNT in dispersion, and then the redox polymer is added in such a way as to form a sample that is placed on the surface of the glassy carbon electrode to form an electrode.

The electrodes that are formed according to the two techniques that are described do not consist of a CNT fiber. The electrochemical processes on such electrodes are confined to the surfaces of the electrodes, which limits the currents that are obtained.

Contrary to this technology, an organization and an orientation of the CNT on the nanometric scale result from this invention. The assembly in the form of fibers makes it possible to obtain a three-dimensional electrode that thereby exhibits an increase of the specific surface area relative to those of the prior art.

It will also be possible to refer to the document D2, WO 2005/075663. This document describes a process that is similar to the one described in D1. Actually, the process that is described consists in mixing a biological compound such as a biopolymer (enzyme, DNA), with a nanostructured material, such as, for example, CNT in a solution, mixing the solution to form a dispersion, and removing the thus obtained nanostructured composite material. The nanotubes are assembled, whereas they are covered by biological compounds. These compounds can constitute insulating barriers for the passage of the current between nanotubes, which is detrimental to a use as an electrode.

According to this invention, the biological compounds are provided on the nanotubes after the latter have been assembled in the form of fibers. The initial assembly of the nanotubes in the form of a fiber makes it possible to maximize the effectiveness of the contacts between nanotubes and consequently the conductivity of the electrode.

Finally, reference can also be made to the prior art that constitutes the document D3, WO 2004/020453. This document relates to a functional nanoparticle that comprises a nanoparticle that is conductive (metal) or semi-conductive or made of CNT, and a bi-functional protein. The proteins that are described have two areas of activity; one of these areas is used to attach the protein to the nanotube. Applications are described for metallic or semi-conductive nanoparticles. Such nanoparticles make it possible to produce nanometric bonds for electronic circuits or assemblies that form networks with high integration of metallic nanoparticles. However, no description relative to the production of an electrically conductive fiber and the use of such a fiber for producing an electrode is either given or even suggested.

In conclusion, the existing solutions produce unsatisfactory results for the operation of bioelectrochemical systems. With the carbon fibers, the specific surface area is too small to make it possible to obtain an adequate current density and consequently a conductivity that is suitable for applications such as bioelectrochemical systems such as biobatteries or biosensors.

Invention

This invention has as its object to solve the problem of the production of electrically conductive fibers for applications such as bioelectrochemical systems like, for example, biosensors and biobatteries that are used in particular in biomedical applications.

This problem is solved by means of bioactive fibers that have a high specific surface area and a conductivity that make it possible to obtain detection limits or the powers required in bioelectrochemical systems, such as the biosensors or biobatteries.

This invention more particularly has as its object electrically conductive fibers that are primarily characterized in that they consist of assembled carbon nanotubes that are covered by a deposit that comprises at least one biopolymer.

The biopolymer can be selected from among the natural proteins or synthetic proteins, such as, for example, enzymes.

The deposit can also comprise one or more redox polymer(s) for improving the conductive properties of fibers.

The biopolymer can be selected from among the nucleic acids, for example DNA or RNA.

Another object of the invention relates to the process for manufacturing said fibers. This process comprises the stages that consist in producing fibers that consist of carbon nanotubes and in making one or more deposit(s) on the fibers, of which one comprises at least one biopolymer.

The deposit can be made by quenching or immersing the fibers in a solution that contains at least one biopolymer or else by deposition of the solution that contains at least one biopolymer on the fibers or else by electrodeposition. The deposition, for example by coating or spraying, is particularly suitable in the case where it is sought to cover selected segments of fibers.

The deposit on the fibers also comprises one or more redox polymer(s). This deposit is made at the same time as the deposit on the biopolymer(s) by the same technique as the one that is used for the biopolymer.

The deposit of the redox polymer(s) can also be carried out before the deposit of the biopolymer(s) by the technique of immersion or electrodeposition or deposition.

In one embodiment, the process for the production of fibers that consist of carbon nanotubes comprises the spinning of fibers obtained by coagulation of the nanotubes from a dispersion of nanotubes in an aqueous or organic solvent.

In the case where the coagulation of the nanotubes comprises the use of a binder, the process also comprises a stage for removing the binder before making the deposit.

The removal of the binder consists in heating the fibers to the decomposition temperature of the binder.

To not degrade the properties of the carbon nanotubes, the binder that is used is a binder whose decomposition temperature does not exceed 700° C. For example, polyvinyl alcohol (PVA) is selected, and the heating of the fibers is preferably implemented under inert atmosphere and at a temperature that can be between 300° C. and 1100° C. and that is preferably selected at 600° C.

The invention also relates to the production of carbon nanotube fiber electrodes as described above. Such electrodes consist of a fiber segment of carbon nanotubes that are assembled covered by a deposit that comprises at least one biopolymer according to the invention.

The electrodes can consist of a fiber segment of which only one end comprises the biopolymer deposit and optionally one redox polymer.

The electrodes as defined above are particularly suited to use in bioelectrochemical systems such as biobatteries or biosensors.

The improvement of the conductivity properties of the fibers according to this invention makes possible the production of microelectrodes, namely electrodes that consist of a fiber segment with a length that is less than 5 centimeters, 1 to 3 cm, for example, and 1 to 100 micrometers in diameter. The improvement of these properties also makes possible the use of microelectrodes in biomedical systems that can be implanted in the human body.

Other special features and advantages of the invention will clearly emerge from reading the description that is given below and that is provided by way of illustrative and nonlimiting example and opposite the figures in which:

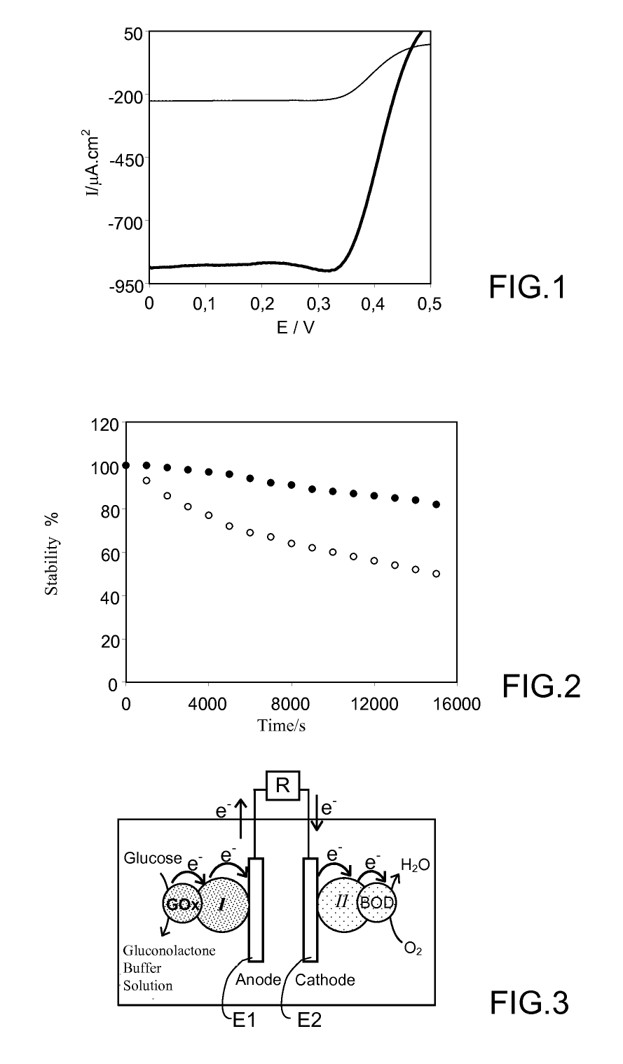

FIG. 1 shows the current density curves in the case of an electroreduction of oxygen, for a conventional carbon fiber electrode and for an electrode according to the invention;

FIG. 2 shows the curves of variation over time of the electroreduction of oxygen for a conventional carbon fiber and for a fiber according to this invention,

FIG. 3 shows the diagram of a biobattery that is equipped with electrodes according to this invention,

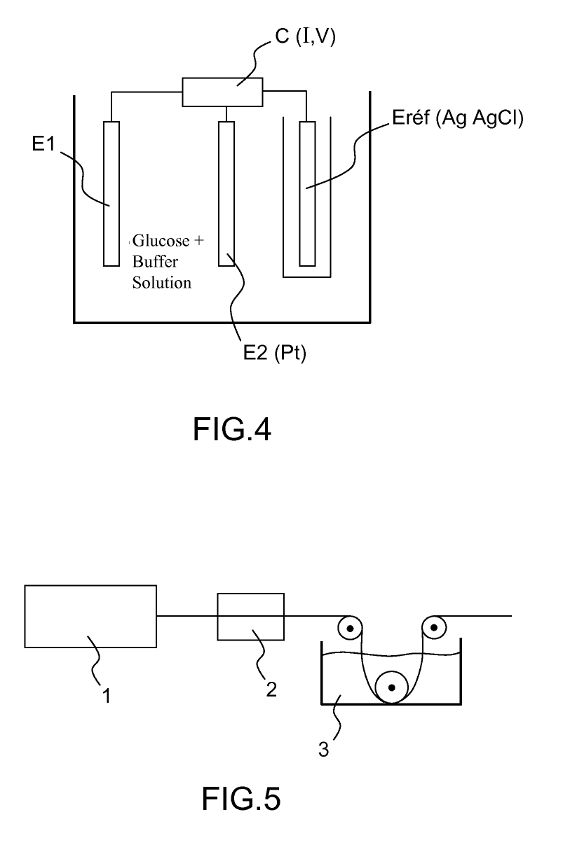

FIG. 4 shows the diagram of a biosensor that is equipped with electrodes according to this invention,

FIG. 5 shows the diagram of the stages of the process for manufacturing fibers according to the invention.

The electrically conductive fibers according to this invention are fibers that have a very high specific surface area relative to the fibers of the prior art; this specific surface area is greater than 50 m2/g.

Such fibers are obtained by manufacturing fibers that consist only of assembled carbon nanotubes: stage bearing the reference 1 in FIG. 5, and then, by treating these fibers to make them bioelectroactive: stage 3 in FIG. 5.

This treatment consists in covering them with a biopolymer that is selected according to the different applications. The fibers that are obtained thus consist of assembled carbon nanotubes and a deposit that comprises at least one biopolymer. The deposit can also comprise a polymer that is also named a redox polymer.

The biopolymer can be selected from among:
The natural proteins or synthetic proteins and more particularly from among the enzymes;
The nucleic acids such as, for example, the DNA, and the RNA.

According to one embodiment, the fibers are obtained, for example, from the manufacturing process that is described in the patent application WO0163028. This process makes it possible to obtain fiber that consists only of carbon nanotubes that are assembled and oriented on the macroscopic scale by coagulation of nanotubes starting from a dispersion of nanotubes in an aqueous or organic solvent. However, the fibers that are obtained by this process comprise a binder that it is necessary to remove for the applications considered, i.e., bioelectrochemical applications.

One advantage of this process is that it makes possible the manufacturing of fibers from single-wall, double-wall or multi-wall nanotubes that are produced in bulk.

Another advantage is that the fibers of nanotubes in the presence of polymer binder that are developed according to the process that is described in this patent application WO0163028 are flexible enough to be folded and embedded without being broken, contrary to conventional carbon fibers.

The presence of binders that facilitate the spinning in manufacturing limits the specific surface area and the conductivity of fibers; this is why it is necessary for this invention to eliminate the binder so as to release the surface of the carbon nanotubes.

In this embodiment, the process for the manufacturing of fibers according to this invention therefore comprises an additional stage, a stage bearing the reference 2 in FIG. 5, consisting in eliminating the binder that is used by a high-temperature treatment.

The binder that is used in the manufacturing of such fibers will be selected so that it is easy to eliminate it without the properties of the carbon nanotubes being degraded. It is possible, for example, to select the polyvinyl alcohol (PVA). This binder is a polymer that ensures good coagulation of the nanotubes in the spinning process. It can be degraded by a heat treatment starting from 300° C. This binder is degraded to more than 95% by a heat treatment at 600° C. in a non-oxidizing atmosphere. At this temperature, the nanotubes are in no way degraded.

After this heat treatment, the fibers consist exclusively of carbon nanotubes.

Preferably, the orientation of the nanotubes will be controlled by stretching that is done before thermal annealing of the fibers. The stretching before annealing makes it possible to modulate and control their electrical conductivity as well as their diameter, their density, and capacitance.

Thus, the fibers that consist only of nanotubes have a very high specific surface area, greater than 50 m2/g. They have a diameter of 1 to 100 microns and a density that can go up to 1.8 g/cm3.

The structure of such fibers allows an effective use of carbon nanotubes for electrochemical applications.

The process for manufacturing fibers according to the invention also comprises a treatment that is made in one or more stages, according to the type of fibers, to adapt them to the bioelectrochemical properties.

This treatment consists in covering the fibers with bioelectroactive (or biospecific) radicals and more particularly with one or more selected biopolymer(s). This stage bears the reference 3 in FIG. 5.

The selection of the biopolymers is made according to the applications.

The treatment that makes it possible to make the fibers bioelectroactive can, for example, consist in quenching the fibers in solutions that contain the required radical(s), i.e., the selected polymer(s), or by immersing the latter with these solutions or else by initiating a deposition of the solution on the fibers (for example, by coating them or by spraying them) or else by making an electrodeposition of the solution on the fibers by application of a potential in the solution.

The very strong interaction of the nanotubes with the polymers ensures increased absorption stability. The absorption stability is critical for the stability of the sensor or biobattery systems. The fibers according to the invention thus ensure an operating period that is quite superior to the one that is accessible by traditional carbon materials.

To accelerate the bioreactions, a second treatment is provided that consists in covering the fibers of the redox polymer that is adapted to the selected biopolymer.

In a practical way, the deposit of the redox polymer(s) can be made at the same time as the deposit of the polymer or may have been made before, and this by the same techniques: immersion, electrodeposition, deposition.

In the case of an electrodeposition or co-electrodeposition, it will be possible to use the Gao et al. method: “Electrodeposition of Redox Polymers and Co-Electrodeposition of Enzymes by Coordinative Crosslinking,” Zhiqiang Gao, Gary Binyamin, Hyug-Han Kim, Scott Calabrese Barton, Yongchao Zhang, and Adam Heller, Angew. Chem. Int. Ed. 2002, 41, No. 5, 810-813.

The process for obtaining carbon nanotube fibers can, in a variant embodiment, be implemented by coagulation without a polymer binder according to the process that is described in, for example, the article by J. Steinmetz, M. Glerup, M. Paillet, P. Bernier and M. Holzinger entitled “Production of Pure Nanotube Fibers Using a Modified Wet-Spinning Method,” published in the publication Carbon, 43(11): 2397-2400, 2005. The subsequent treatment stage(s) of the carbon nanotube fibers that are thus obtained are the same as described above. This solution offers the advantage of not requiring the heat treatment stage for the elimination of the binder.

This second embodiment can, for example, be reserved for a non-continuous production of fibers. Actually, spinning without a polymer binder is much more difficult and is unsuitable for continuous production of homogeneous fibers of adequate mechanical strength.

Other processes for manufacturing fibers that consist of carbon nanotubes can also be used, such as, for example:
The process of coagulation using a static bath as described by L. M. Ericson, H. Fan, H. Q. Peng, V. A. Davis, W. Zhou, J. Sulpizio, Y. H. Wang, R. Booker, J. Vavro, C. Guthy, A. N. G. Parra-Vasquez, M. J. Kim, S. Ramesh, R. K. Saini, C. Kittrell, G. Lavin, H. Schmidt, W. W. Adams, W. E. Billups, M. Pasquali, W. F. Hwang, R. H. Hauge, J. E. Fischer, and R. E. Smalley “Macroscopic, Neat, Single-Walled Carbon Nanotube Fibers,” and published in Science, 305 (5689): 1447-1450, 2004.
The Direct Synthesis Processes. They allow the production of 100% nanotube fibers as described by:
H. W. Zhu, C. L. Xu, D. H. Wu, B. Q. Wei, R. Vajtai, and P. M. Ajayan “Direct Synthesis of Long Single-Walled Carbon Nanotube Strands” and published in Science, 296 (5569): 884-886, 2002.
M. Zhang, K. R. Atkinson, and R. H. Baughman “Multifunctional Carbon Nanotube Yarns by Downsizing an Ancient Technology” and published in Science, 306 (5700): 1358-1361, 2004.
Y. L. Li, I. A. Kinloch, and A. H. Windle “Direct Spinning of Carbon Nanotube Fibers from Chemical Vapor Deposition Synthesis” and published in Science, 304 (5668): 276-278, 2004.

The fibers according to the invention are biospecific and have a large specific surface area, a high electrical conductivity, and an increased stability relative to the electrodes of the prior art; they meet the needs encountered for the production of electrodes in bioelectrochemical systems.

The characteristics of the fibers according to the invention are clearly demonstrated starting from the embodiment described below.

In this example, a bioelectrocatalysis has been implemented with a carbon fiber of the prior art, and then with a fiber according to the invention. The comparative results are illustrated by FIGS. 1 and 2; the results relative to the carbon fiber are shown by fine lines, and those of the fiber according to the invention are shown by thick lines.

### Example

In this example, a traditional carbon fiber and a carbon nanotube fiber that is obtained as described above are the object of a deposit in such a way as to be covered by an enzyme such as bilirubin oxidase and its redox polymer PAA-PVI-[Os(4,4′-dichloro-2,2′-bipyridine)2Cl]+/2.

The comparative measurements were carried out by initiating an electroreduction of O2 on a carbon fiber electrode (thin lines) and on a nanotube fiber electrode according to the invention (thick lines) under the following conditions: solution with a 20 mmol phosphate buffer, 0.14 M of NaCl, pH 7.2, 37.5 C, 1 mV.s-1. The composition of the bioelectrocatalyst that is used for covering the electrodes, object of the comparison: 32% by weight of bilirubin oxidase, 60.5% by weight of PAA-PVI-[Os (4,4′-dichloro-2,2′-bipyridne) 2Cl]+/2+, and 7.5% by weight of cross-linking agent (polyethylene glycol (400) diglycidyl ether).

As FIG. 1 shows, with +0.3 V/AgAgCl, it is possible to reduce the O2 of H2O to a current density of 880 μA.cm-2 on the carbon nanotube fiber electrode and only 215 μA.cm-2 on a carbon fiber electrode. This value further represents the most important value recorded to date for the reduction of O2 on a fiber. This clearly demonstrates the advantage of using carbon nanotube fibers instead of carbon fibers.

By increasing the specific surface area of the electrode, not only is the boundary current density increased, but this also makes it possible to improve the enzyme kinetics with the electrode and to reduce its potential and, in this precise case, to reduce the reduction overpotential of the oxygen.

In addition, the use of carbon nanotube fibers instead of carbon fiber also makes it possible to increase the stability of the system. These results have been demonstrated by implementing stability tests, in a physiological environment, by using the electrodes as described above.

FIG. 2 illustrates the evolution over time of the electroreduction of O2 on the carbon fiber electrode (white circles) and on the carbon nanotube fiber electrode according to the invention (black circles) under the following conditions: a 20 mmol phosphate buffer solution, 0.14 M of NaCl, pH 7.2, 37.5 C, 1 mV.s-1. Composition of the bioelectrocatalyst: 32% by weight of bilirubin oxidase, 60.5% by weight of PAA-PVI-[Os (4,4′-dichloro-2,2′-bipyridine) 2Cl]+/2+, and 7.5% by weight of cross-linking agent (polyethylene glycol (400) diglycidyl ether).

As FIG. 2 illustrates, after 4 hours of continuous operation, the current density has decreased by 50% with the carbon fiber electrode, but only by 15% with the carbon nanotube fiber electrode according to the invention.

With such carbon nanotube fiber electrodes, it is possible to produce biobatteries according to conventional concepts as is illustrated by the diagram of FIG. 3.

In the diagram of FIG. 3, the anode and the cathode are electrodes that are obtained from carbon nanotube fibers as described above. These electrodes consist of carbon nanotube fibers that are covered by their respective bioelectrocatalysts and reside in the same solution. The electrodes are connected to a component R and make it possible to supply electrical power to this component using the following reactions:

With the anode, the electrons are transferred from the glucose to the glucose oxidase (GOx), from the GOx to the redox polymer I, and from the redox polymer I to the electrode. With the cathode, the electrons are transferred from the cathode to the redox polymer II, from the redox polymer II to the bilirubin oxidase (BOD), and from the BOD to the O2.

In the system that is illustrated in this diagram, after oxidation of the glucose of δ-gluconolactone by the glucose oxidase (GOx), the electrons are transported to the anode by the redox polymer I. (Equation 1) The electrons are then transported from the cathode to the bilirubin oxidase (BOD) by the redox polymer II, which then catalyzes the reduction of O2 into water (Equation 2). The equation 3 shows the overall reaction of the small battery.

β-D-glucose→δ-gluoconolactone+2H++2e− (1)

O2+4H++4e−→2H2O (2)

2β-D-glucose+02→2δ-gluconolactone+H2O (3)

Once implanted in the human body, a biobattery as described can produce several microwatts and can supply an independent biodetector-emitter R, which records, for example, the local concentration of glucose, suitable for the management of diabetes or local temperature, control of the infection of an internal wound after surgery or microsurgery.

By way of example, an experiment implemented with such a biobattery in the presence of air and 15 mmol of glucose made it possible to obtain a power of 600 μW.cm⁻². Under the same experimental conditions, a biobattery made with carbon fibers made it possible to obtain a power of only 180 μW.cm⁻².

The diagram of FIG. 4 illustrates the application of the invention to the production of a biosensor. The biosensor comprises three electrodes, one anode E1, a counter-electrode E2, and a reference electrode E_{ref}. The anode El consists of carbon nanotube fibers that comprise a deposit of bioelectrocatalyst, i.e., a selected biopolymer or redox polymer. This anode resides in a solution of chemical radicals that are suitable for the measurement being carried out. The cathode is the reference electrode E_{ref}, i.e., the electrode that is brought to a stationary potential immersed in a buffer solution. If the same bioelectrocatalyst as in the given example is used for the FIG. 3 reactions, the measurement of the potential in the anode relative to that of the cathode provides information on the presence and the quantity of glucose.

The electrodes E1, E2 and E_{ref} are connected to a sensor- or detector-type component C (potentiostat), which makes it possible to carry out a current measurement or voltage resulting from the bioelectrocatalysis.

The fibers according to the invention are applied in all bioelectrochemical systems.

The list below is provided by way of nonlimiting example to illustrate enzymes that can be selected according to the desired application. A substrate for the production of a biobattery or a biosensor was also associated with each enzyme:

1—Glucose oxidase/glucose (or all sugars being oxidized by this enzyme)

2—Lactate oxidase/lactate

3—Pyruvate oxidase/pyruvate

4—Alcohol oxidase/alcohol

5—Cholesterol oxidase/cholesterol

6—Glutamate oxidase/glutamate

7—Pyranose oxidase/pyranose

8—Choline oxidase/choline

9—Cellobiose dehydrogenase/cellobiose

10—Glucose dehydrogenase/glucose

11—Pyranose dehydrogenase/pyranose

12—Fructose dehydrogenase/fructose

13—Aldehyde oxidase/aldehyde

14—Gluconolactone oxidase/gluconolactone

15—Alcohol dehydrogenase/alcohol

16—Bilirubin oxidase/oxygen

17—Laccase/oxygen

18—Ceruloplasmin/oxygen

19—Ascorbate oxidase/oxygen or ascorbate

20—Horseradish peroxidase/H₂O₂

The fibers according to the invention can be manufactured continuously. Their cross-section may or may not be circular, and the largest dimension of the cross-section can be between 10 nm and 1 mm.

Any type of nanotube can be used for their manufacture. The deposit of the biopolymer can be implemented by immersion or quenching in a solution that comprises the desired biopolymer (enzyme or DNA or RNA), or by electrodeposition, electrodeposition being done in a known manner by application of an electrical potential to the solution.

In the cases where a redox polymer is used for accelerating the conduction process, this redox polymer can be in the same solution as the biopolymer; the redox polymer is then deposited at the same time as the polymer or is co-electrodeposited. By way of example, the polymer and biopolymer concentrations can range from 0.1 mg/ml to 10 mg/ml, and the thickness of the biopolymer deposit can range from several angstroms to several micrometers.

The polymer concentrations are selected in such a way as to have a control of the thickness of the deposit and more specifically the quantity of biopolymer that is deposited.

The production of electrodes from such fibers consists in cutting fiber segments to the desired length. It thus is possible to use any length.

In most of the applications, and this is the case for the use of electrodes in the production of biobatteries or biosensors, a very short length will be selected, whereby the lengths of said electrodes do not exceed, for example, 5 cm, preferably 1 to 3 cm. It is a matter of microelectrodes of 1 to 30 micrometers in diameter and 1 to 3 cm in length that can be implanted under the skin or in any living organism.

A selective deposit can be made on the fibers. Each fiber will then be covered only on the segments of predetermined length. The production of electrodes from these fibers consists in cutting fiber segments in such a way as to have the deposit (biopolymer and optionally redox polymer) only at one end of the segment. Such electrodes can be used in the production of neurobiological probes, for example.

The fibers that are described in this invention can be used in forms of wires and multi-filament strips, mats, woven structures or non-woven structures.

1. Electrically conductive fibers, characterized in that they consist of assembled carbon nanotubes that are covered by a deposit that comprises at least one biopolymer.

2. Electrically conductive fibers according to claim 1, wherein the biopolymer is selected from among the natural proteins or the synthetic proteins.

3. Electrically conductive fibers according to claim 2, wherein the natural or synthetic proteins are enzymes.

4. Electrically conductive fibers according to claim 3, wherein the deposit also comprises one or more redox polymer(s).

5. Electrically conductive fibers according to claim 1, wherein the biopolymer is selected from among the nucleic acids, for example DNA or RNA.

6. Process for manufacturing fibers according to claim 1, wherein it comprises the following stages:
Production of fibers that consist of carbon nanotubes,
Making at least one deposit on these fibers that comprise at least one biopolymer.

7. Process for manufacturing fibers according to claim 6, wherein the production of fibers that consist of carbon nanotubes comprises the spinning of fibers obtained by coagulation of carbon nanotubes from a dispersion of carbon nanotubes in an aqueous or organic solvent.

8. Process for manufacturing fibers according to claim 6, wherein it consists in making a deposit on the fibers that also comprise one or more redox polymer(s).

9. Process for manufacturing fibers according to claim 6, wherein the deposit is made by quenching or immersing fibers in a solution that contains at least one biopolymer, or by electrodeposition or else by deposition (coating or spraying).

10. Process for manufacturing fibers according to claim 8, wherein the deposit of the redox polymer(s) is made at the same time as the deposit of the biopolymer(s).

11. Process for manufacturing fibers according to claim 8, wherein the deposit of the redox polymer(s) is made before the deposit of the biopolymer(s).

12. Process for manufacturing fibers according to claim 6, wherein the deposit is made on the selected fiber segments by deposition (coating or spraying).

13. Process for manufacturing fibers according to claim 7, according to which the coagulation of the nanotubes comprises the use of a binder, wherein it also comprises a stage for removal of the binder before the deposition stage(s).

14. Process for manufacturing fibers according to claim 13, wherein the removal of the binder consists in heating the fibers to the melting point of the binder.

15. Process for manufacturing fibers according to claim 13, wherein the binder that is used is polyvinyl alcohol (PVA), and the heating of the fibers is done between 300° C. and 1100° C., and preferably at 600° C. under inert atmosphere.

16. A structure comprising the fibers according to claim 1, wherein said structure is in a form selected from the group consisting of: wires and multi-filament strips, mats, woven structures and non-woven structures.

17. Electrodes, wherein they are made of carbon nanotube fibers, according to claim 1.

18. Electrodes according to claim 17, wherein they consist of a fiber segment with a length that is less than or equal to 5, preferably between 1 and 3 cm, and whose diameter can range from 1 to 30 micrometers.

19. Electrodes according to claim 17, wherein they consist of a fiber segment of which only one end comprises a deposit.

20. A bioelectrochemical system comprising an electrode as defined according to claim 17.

21. A biobattery comprising an electrode as defined according to claim 17.

22. A biosensor comprising an electrode as defined according to claim 17.
